(19) United States
(12) Patent Application Publication
(10) Pub. No.: US 2007/0038920 A1
(43) Pub. Date: Feb. 15, 2007

(54) Information recording-reproducing apparatus and method of recording and reproducing information

(76) Inventors: Naoto Mihara, Yokohama-Shi (JP); Toshihiko Kaneshige, Yokohama-Shi (JP); Toru Uno, Yokohama-Shi (JP); Hiroaki Morino, Yokohama-Shi (JP); Yukiyasu Tatsuzawa, Yokohama-Shi (JP); Minako Morio, Kawasaki-Shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/494,421

(22) Filed: Jul. 27, 2006

(30) Foreign Application Priority Data
Jul. 28, 2005 (JP) 2005-219613

(51) Int. Cl. G11C 29/00

(52) U.S. Cl. 714/766

(57) ABSTRACT

An information recording-reproducing apparatus includes a recording-reproducing unit configured to record information given by encoding the data in predetermined data blocks with an error correction code, the data blocks being generated by multiplexing information indicating the positions of the defect management areas, on the information storage medium and to decode the encoded information with the error correction code and reproduce the decoded information and a complementary unit configured to complement the information indicating the positions of the defect management areas on the basis of the data in data units smaller than the data blocks, when an error can be corrected in the data units or when no error is detected even if the error correction in the data blocks cannot be performed for the information that is encoded and recorded.

### PRIORITY INFORMATION

This application is based on and claims priority to Japanese Patent Application No. 2005-219613, filed on Jul. 28, 2005, the entire contents of which is incorporated herein by reference.

### BACKGROUND OF THE INVENTION

1. Field of the Invention

The present invention relates to information recording-reproducing apparatuses and methods of recording and reproducing information. More particularly, the present invention relates to an information recording-reproducing apparatus and a method of recording and reproducing information, which are capable of recording and reproducing the information on and from, for example, a rewritable optical disc.

2. Description of the Related Art

Known information storage media, such as optical discs, capable of rewriting information recorded thereon have complementary mechanisms for “defective parts in recording” caused on the information storage media. Areas used for managing the defective parts are called “defect management areas” (hereinafter abbreviated to “DMAs”).

The DMAs are overwritten as the defective parts increase in number. Since the information storage media are generally deteriorated due to the overwriting of the DMAs, the information storage media are limited in the allowable number of overwriting times. In the case of media (for example, high-density optical discs using blue lasers) having a relatively small allowable number of overwriting times, the overwriting involved in the update of the DMAs causes a problem. In other words, the overwriting develops defects in the DMAs themselves in which the defect management information is recorded.

In order to resolve such a problem, for example, USP No. 20010026511 discloses an information recording medium capable of storing the defect management information in multiple areas that are physically separated from each other to provide redundancy and capable of compensating for the defect management information in any DMA having a defect with the defect management information stored in other areas.

The information storage medium, such as an optical disc, disclosed in USP No. 20010026511 has a spare area, in addition to a user area in which general data (user data) is stored. If the user area has a defective part, the user data to be stored in the defective part is stored in the spare area. The shift of the data is performed for every predetermined data unit, which is called an ECC block.

In order to reproduce (read out) the shifted user data, it is necessary to provide the defect management information used for associating the address information about the defective source area with the address information about the destination area. The defect management information is stored in the DMAs, which are arranged in areas other than the user area and the spare area.

Known DVD-RAMs and next generation high-density optical discs, including HD DVD-RAMs, are each structured so as to have four DMAs including two DMAs at the innermost edge of the optical disc and two DMAs at the outermost edge thereof. The same defect management information is stored in the four DMAs. Accordingly, even if dust is gathered or any scratch is made in a certain DMA, the reliability of the defect management information can be improved because the defect management information in the other DMAs is effective.

In HD DVD-RAMs having an allowable number of overwriting times smaller than that of the DVD-RAMs, the four DMAs each have multiple DMAs, for example, 100 DMAs. If the number of times a DMA is overwritten is to exceed an allowable number of overwriting times or the error ratio of the data in a DMA is not within a predetermined range, the defect management information in the DMA is shifted to another DMA to replace the DMA with the other DMA. If the number of times the alternative DMA is overwritten is to exceed the allowable number of overwriting times or the error ratio of the data in the alternative DMA is not within the predetermined range, the alternative DMA is replaced with another DMA. This replacement can be repeated up to 100 times.

When multiple, for example, 100 DMAs exist on a disc, it is necessary to determine which DMA is the latest (current) DMA. In order to determine the latest DMA in a short time, areas in which DMA managers are recorded are further provided on the HD DVD-RAM or the like.

Each DMA manager has the positional information about the four latest DMAs. Referring to the positional information allows the positions of the latest DMAs to be immediately determined. The DMA manager is also deteriorated as the number of overwriting times is increased. Hence, multiple DMA managers are arranged at positions physically separated from each other. If the number of times a DMA manager is overwritten is to exceed an allowable number of overwriting times or the error ratio of the data in a DMA manager is not within a predetermined range, the DMA manager is replaced with another DMA manager.

The multiple same positional information or the like of the DMAs are recorded in one DMA manager. In addition, the positional information in the DMAs is encoded with error correction codes for every predetermined data unit (this data unit is called the ECC block), like the general user data. Consequently, errors the error ratio of which is within a predetermined range can be corrected with the error correction codes in units of the ECC blocks.

However, if the error ratio of the data exceeds a correctable error ratio due to a defect on the medium or the like, errors cannot be corrected in units of the ECC blocks and, therefore, the information about the DMA manager cannot be read out. Accordingly, it becomes impossible to employ a method of reading out the positional information about the latest DMA from the DMA manager to refer to the DMA (this method is referred to as a table lookup method). Consequently, it is necessary to employ, for example, a method of sequentially searching the 100 DMAs from the first one for the latest DMA (this method is referred to as an incremental method). As a result, it takes a long time before the latest DMAs are accessed.

### SUMMARY OF THE INVENTION

In order to resolve the above problems, it is an object of the present invention to provide an information recording-reproducing apparatus and a method of recording and reproducing information, which are capable of reading out the positional information about the latest DMA stored in a DMA manager to access the DMA in a short time even if the error ratio per ECC block exceeds the error correction capability.

According to an embodiment of the present invention, there is provided an information recording-reproducing apparatus including a first recording-reproducing unit configured to record user data in a user area on an information storage medium and to reproduce the user data; a shifting unit configured to shift the user data that cannot be recorded in a defect area in the user area to a spare area on the information storage medium and to reproduce the shifted user data; a second recording-reproducing unit configured to record defect management information used for reproducing the user data shifted to the spare area in a plurality of defect management areas on the information storage medium and to reproduce the defect management information; a third recording-reproducing unit configured to record information given by encoding the data in predetermined data blocks with an error correction code, the data blocks being generated by multiplexing information indicating the positions of the defect management areas, on the information storage medium and to decode the encoded information with the error correction code and reproduce the decoded information; and a complementary unit configured to complement the information indicating the positions of the defect management areas on the basis of the data in data units smaller than the data blocks, when an error can be corrected in the data units or when no error is detected even if the error correction in the data blocks cannot be performed for the information that is encoded and recorded.

According to another embodiment of the present invention, there is provided a method of recording and reproducing information. The method includes the steps of recording user data in a user area on an information storage medium and reproducing the user data; shifting the user data that cannot be recorded in a defect area in the user area to a spare area on the information storage medium and reproducing the shifted user data; recording defect management information used for reproducing the user data shifted to the spare area in a plurality of defect management areas on the information storage medium and reproducing the defect management information; recording information given by encoding the data in predetermined data blocks with an error correction code, the data blocks being generated by multiplexing information indicating the positions of the defect management areas, on the information storage medium and decoding the encoded information with the error correction code to reproduce the decoded information; and complementing the information indicating the positions of the defect management areas on the basis of the data in data units smaller than the data blocks, when an error can be corrected in the data units or when no error is detected even if the error correction in the data blocks cannot be performed for the information that is encoded and recorded.

According to the information recording-reproducing apparatus and the method of recording and reproducing information of the present invention, it is possible to read out the positional information about the latest DMA stored in the DMA manager to access the DMA in a short time even if the error ratio per ECC block exceeds the error correction capability.

### BRIEF DESCRIPTION OF THE DRAWINGS

FIG. 1 is a diagram schematically showing an example of the physical data arrangement on an information storage medium on and from which an information recording-reproducing apparatus according to an embodiment of the present invention records and reproduces information;

FIGS. 2A and 2B show examples of the data structure of the information storage medium on and from which the information recording-reproducing apparatus according to the embodiment of the present invention records and reproduces information;

FIGS. 3A and 3B show examples of the data structure of the information storage medium on and from which the information recording-reproducing apparatus according to the embodiment of the present invention records and reproduces information;

FIG. 4 shows an example of the data structure of the information storage medium on and from which the information recording-reproducing apparatus according to the embodiment of the present invention records and reproduces information;

FIGS. 5A and 5B show examples of the data structure of the information storage medium on and from which the information recording-reproducing apparatus according to the embodiment of the present invention records and reproduces information;

FIGS. 6A and 6B are basic flowcharts showing an exemplary process of reading out and complementing information in a DMA manager in the information recording-reproducing apparatus according to the embodiment of the present invention;

FIG. 7 is a detailed flowchart showing the exemplary process of reading out and complementing the information about the DMA manager in the information recording-reproducing apparatus according to the embodiment of the present invention;

FIG. 8 is another detailed flowchart showing the exemplary process of reading out and complementing the information about the DMA manager in the information recording-reproducing apparatus according to the embodiment of the present invention;

FIG. 9 is another detailed flowchart showing the exemplary process of reading out and complementing the information about the DMA manager in the information recording-reproducing apparatus according to the embodiment of the present invention;

FIGS. 10A and 10B are other detailed flowcharts showing the exemplary process of reading out and complementing the information about the DMA manager in the information recording-reproducing apparatus according to the embodiment of the present invention; and

FIG. 11 is a block diagram showing an example of the system configuration of the information recording-reproducing apparatus according to the embodiment of the present invention.

### DETAILED DESCRIPTION OF THE PREFERRED EMBODIMENT

An information recording-reproducing apparatus and a method of recording and reproducing information according to embodiments of the present invention will be described with reference to the attached drawings.

(1) Data Structure of Information Storage Medium

The data structure of an information storage medium 1 on and from which an information recording-reproducing apparatus according to an embodiment of the present invention records and reproduces data will be described.

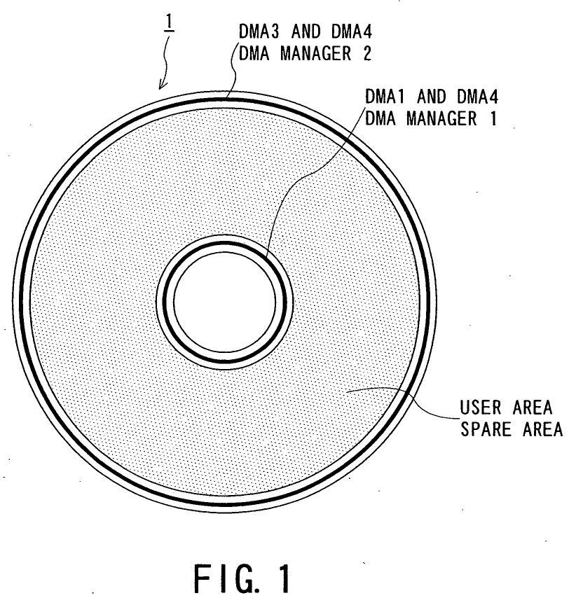

FIG. 1 is a diagram schematically showing an example of the physical data arrangement on the rewritable information storage medium 1, which is typified by a next generation DVD or HD DVD-RAM.

Most part of the recording surface of the information storage medium 1 is occupied by a user area and part of the user area is used as a spare area. The user area has user data recorded therein. The user data includes video data, audio data, and a variety of information data. The spare area is used as an alternative area of a user area in which the data cannot be normally written (a defective area). The data to be written in the defective area is shifted to the spare area.

A ring area called a data lead-out area is provided at the outer edge of the user area (including the spare area as part thereof). The data lead-out area includes defect management areas (DMAs) and an area in which a DMA manager is recorded.

A ring area called a data lead-in area is provided at the inner edge of the user area. The data lead-in area also includes defect management areas (DMAs) and an area in which a DMA manager is recorded.

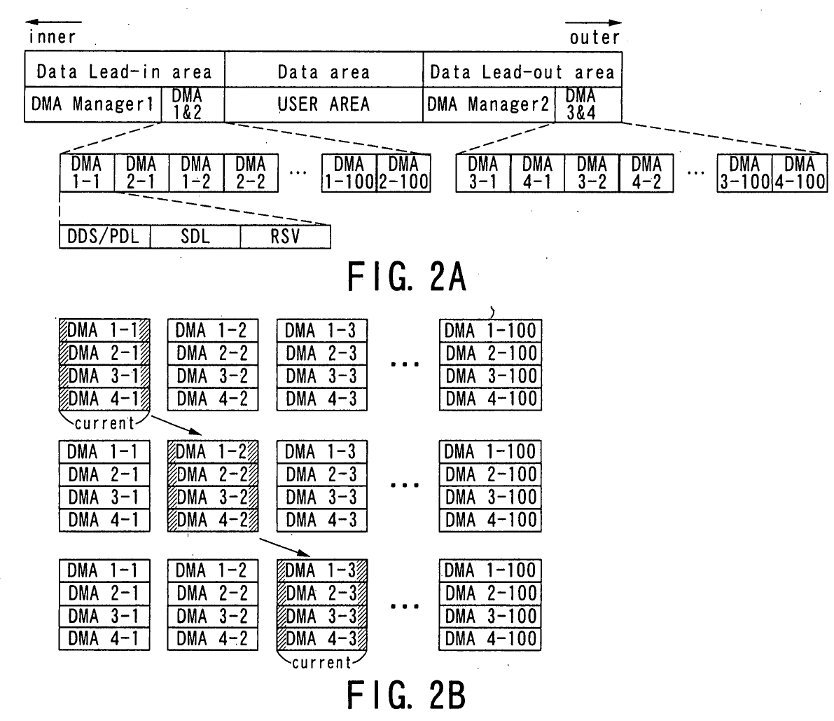

FIG. 2A shows an example of the data structure of the information storage medium 1. As described above, the information storage medium 1 has the data lead-in area at the inner edge thereof and the data lead-out area at the outer edge thereof. The data lead-in area has DMAs 1 and 2 and a DMA manager 1 provided in areas physically separated from each other. Similarly, the data lead-out area has DMAs 3 and 4 and a DMA manager 2 provided in areas physically separated from each other.

The DMA 1 includes 100 DMA units from DMA 1-1 to DMA 1-100, which form one set. Similarly, the DMA 2 includes 100 DMA units from DMA 2-1 to DMA 2-100, which form one set; the DMA 3 includes 100 DMA units from DMA 3-1 to DMA 3-100, which form one set; and the DMA 4 includes 100 DMA units from DMA 4-1 to DMA 4-100, which form one set.

Each DMA unit includes defect management information called a DDS/PDL, defect management information called an SDL, and a reserved area (RSV).

The defect management information recorded in the DMA is used for associating the address (old address) of a data area (a defective area) in which the user data cannot be normally written because of a defect with the address (new address) of the spare area to which the user data that cannot be written is shifted. Even if the user data cannot be written in the data area because the data area has any defect, referring to the defect management information in the DMA to read out the user data in the spare area can ensure reproduction of the user data.

The same defect management information is recorded in the DMAs 1 to 4 physically separated from each other. Accordingly, if the data cannot be read out from a certain DMA due to a defect caused by any scratch or fingerprint, reading out the defect management information from other DMAs improves the fault tolerance of the information storage medium 1.

Since the defect management information about a data area where any new defect occurs is added to the DMA, the defect management information in the DMA is updated (overwritten) each time a defect occurs. The rewritable information storage medium 1 is gradually deteriorated due to the overwriting and the DMA itself is also deteriorated. Accordingly, for example, the HD DVD-RAMs each have multiple (precisely 100) DMAs. If the number of times a certain DMA is overwritten exceeds a predetermined number of times or if the symbol error ratio exceeds a predetermined value (the probability of the data becoming unreadable is increased), the defect management information in the DMA is shifted to the subsequent DMA to replace the defect management information in the DMA with the defect management information in the subsequent DMA. This replacement can be repeated up to 100 times.

FIG. 2B illustrates the replacement of the DMAs.

The DMAs in the respective sets are sequentially used from the first DMAs (the DMA 1-1, the DMA 2-1, the DMA 3-1, and the DMA 4-1). If the information cannot be read out from at least one of the four DMAs or if at least one of the four DMAs requires the replacement, the DMA 1-1 to the DMA 4-1 are simultaneously replaced with the subsequent DMAs (the DMA 1-2, the DMA 2-2, the DMA 3-2, and the DMA 4-2). The simultaneous replacement of the four DMAs is performed in order to facilitate a complementary process if a system failure occurs.

The DMA manager will now be described.

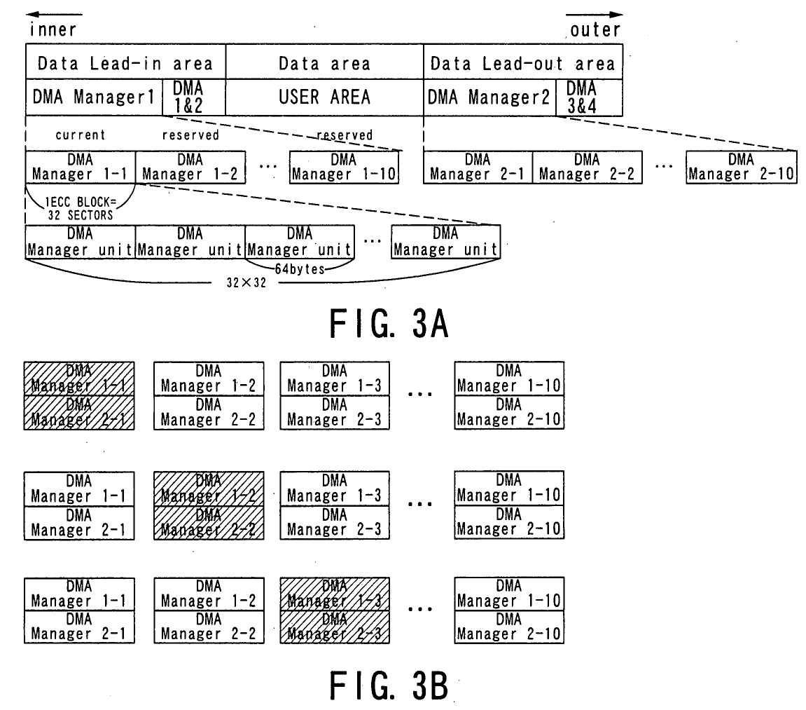

FIG. 3A shows an example of the data structure of the DMA manager. The DMA manager has information indicating where the latest DMA is currently positioned (information indicating the position of the defect management area). Since a time loss occurs in the method of searching the DMAs one by one from the first DMA for the latest DMA (the incremental method), for example, the HD DVD-RAM has the DMA managers provided therein. Referring to the information about the DMA managers allows the latest DMAs to be immediately accessed (this method is called the table lookup method).

As in the case of the DMA, in order to improve the fault tolerance against any defect caused by a scratch or a fingerprint, the DMA managers 1 and 2 are provided in two areas (the data lead-in area and the data lead-out area) physically separated from each other and the same information is recorded in the DMA managers 1 and 2.

Since the DMA managers themselves are deteriorated due to the overwriting, the DMA manager 1 includes ten DMA managers from a DMA manager 1-1 to a DMA manager 1-10 and the DMA manager 2 includes ten DMA managers from a DMA manager 2-1 to a DMA manager 2-10.

FIG. 3B illustrates the replacement of the DMA managers. The DMA managers are sequentially used from the first DMA manager (the DMA manager 1-1 and the DMA manager 2-1). If the information cannot be read out from one of the two DMA managers, the two DMA manages are simultaneously replaced with the subsequent DMA managers (the DMA manager 1-2 and the DMA manager 2-2). The maximum number of replacement times of the DMA manages is ten. Since the number of replacement times of the DMA managers is smaller than that of the DMAs, the latest DMA managers are searched for by the incremental method.

If the information cannot be read out from both of the latest DMA managers 1 and 2, the DMAs cannot be searched for by the table lookup method. Accordingly, it is necessary to employ the incremental method and, therefore, a time loss occurs in the search for the DMAs. An object of the present invention is to provide a mechanism capable of complementing the information in both of the latest DMA managers 1 and 2 even if the information cannot be read out from the latest DMA managers 1 and 2. In order to describe this mechanism, the data structure of the DMA manager will now be described in detail.

One DMA manager includes data blocks called ECC blocks, as shown in FIG. 3A.

In known DVDs and HD DVD-RAMs, an error correction code (ECC) is added in the recording of user data. The ECC is added for every predetermined data size and the unit of this data size is called the ECC block. In the recording of data, the normal recording cannot be performed if the data recorded in units of the ECC blocks is read out for verification and the data cannot be corrected with the error correction code for every ECC block (the number of errors exceeds a correctable number of errors). In the reproduction of data, the normal readout of the data cannot be performed if the readout data cannot be corrected with the error correction code for every ECC block (the number of errors exceeds a correctable number of errors).

As in the general user data, the data is recorded and reproduced in and from the DMA manager in units of the ECC blocks.

The HD DVD-RAM has the ECC blocks each having a data size of 64 KB. The ECC block is divided into units called “sectors” each having a data size of 2 KB. Since the HD DVD-RAM has 32 sectors for every ECC block, the HD DVD-RAM has a data size of 64 KB (32 sectors×2 KB) for every ECC block.

In contrast, the DVD has the sectors each having a data size of 2 KB, as in the HD DVD-RAM, but includes 16 sectors in the ECC block. This number of the sectors of the DVD is half of that of the HD DVD-RAM. Accordingly, the DVD has a data size of 32 KB.

Data units called DMA manager units are multiplexed into one DMA manager. The “multiplexing” here means that the DMA manager has multiple DMA manager units each having the same data. Each DMA manager unit has a data size of 64 bytes and each sector has a data size of 2 KB. Accordingly, 32 DMA manager units are multiplexed into one sector. Since the HD DVD-RAM has 32 sectors for every ECC block, 1,024 (32×32) DMA manager units are multiplexed into one ECC block.

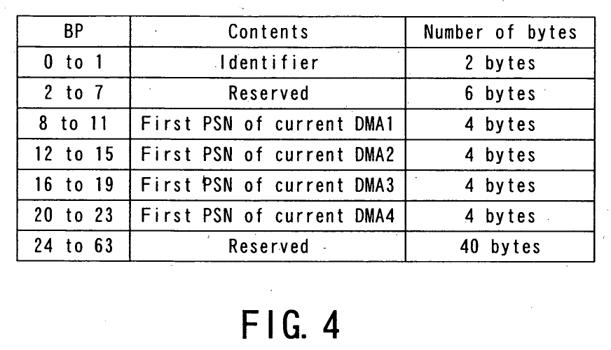

FIG. 4 shows an example of the data structure of one DMA manager unit. A detailed structure of the DMA manager unit including the 64-byte data is shown in FIG. 4.

The first two bytes represent an extension (identifier) and the subsequent six bytes are reserved. The subsequent four bytes represent a “first physical sector number (PSN) of the current DMA 1” indicating the current address information in the DMA 1. The “first physical sector number (PSN) of the current DMA 1” is followed by the four-byte current address information in the DMA 2, the four-byte current address information in the DMA 3, and the four-byte current address information in the DMA 4. The last 40 bytes are reserved. Referring to the current (latest) address information in the DMAs 1 to 4, recorded in one DMA manager unit, by the table lookup method allows the latest DMA to be immediately accessed.

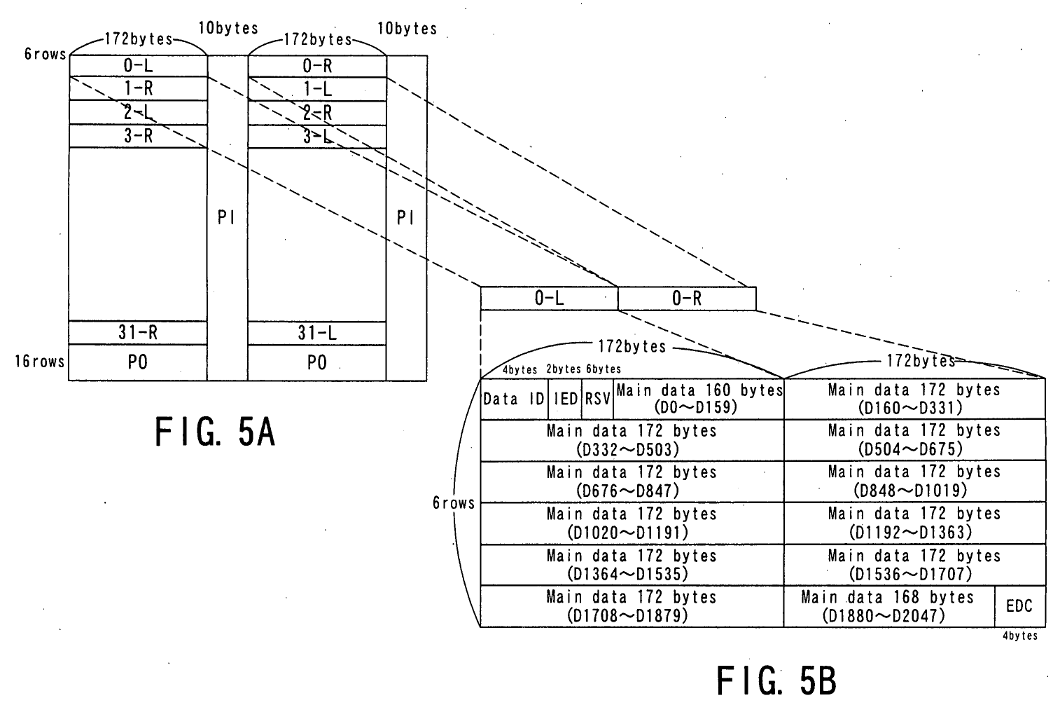

FIG. 5A shows an example of the data structure of each ECC block of the information storage medium 1 (HD DVD-RAM). FIG. 5B shows an example of the data structure of each sector of the information storage medium 1 (HD DVD-RAM).

Referring to FIG. 5B, one sector includes a “data ID” (the identification information about each sector) of four bytes, an “ID error detection (IED)” of two bytes, and a reserved area (RSV) of six bytes. The RSV is followed by main data of 2,048 bytes (2 KB) from D0 to D2047 and an error detection code (EDC) of four bytes.

The EDC is used for error detection from the data of 2,060 bytes from the head of the sector to the trail of the main data (D2047) (the EDC is not used for error correction). The EDC allows determination of whether the data for every sector is effective (whether any error is detected) even if an error cannot be corrected in units of the ECC blocks (described below).

Since the main data area is scrambled, it is necessary to perform the error detection with the EDC for the main data area after it is descrambled.

As shown in FIG. 5B, each sector is divided into 12 “rows” including six rows at the left side and six rows at the right side. One “row” has a data size of 172 bytes.

In order to record the information about the DMA manager in the sector, the data in the 32 DMA manager units each having a data size of 64 bytes (refer to FIG. 4) is recorded in the 2-KB main data areas from D0 to D2047.

The exemplary data structure of each ECC block is shown in FIG. 5A. As described above, the HD DVD-RAM has the 32 sectors from 0 to 31 for every ECC block.

Referring to FIG. 5A, two areas denoted by “0-L” and “0-R” at the top rank of the data sector correspond to the data in the sector numbered “0”, shown in FIG. 5B, divided into the left and right parts each having six rows. Two areas denoted by “1-R” and “1-L” at the second rank of the data sector correspond to the data in the sector numbered “1”, which is given by division into the left and right parts each having six rows and, then, by replacement of the left and right parts with each other. The data in the sectors numbered from “2” to “31” is alternately arranged in the above manner.

In the ECC block, parity codes used for the error correction are added to the data in the 32 sectors. These parity codes include inner parity codes (PI codes) of 10 bytes, which are added for every “row” of 172 bytes, and outer parity codes (PO codes) of 16 rows, which are added to the left and right 192 (6×32) rows. The PI codes are used for the error correction in the row direction and the PO codes are used for the error correction in the column direction.

The two columns each including 182 (172+10) bytes and the 208 rows (6 rows×32+16 rows) form the array of the ECC block including the parity codes.

In the recording of the information about the DMA manager, the data in the 32 sectors each having the same content is recorded in one ECC block. Since the data in the 32 DMA manager units is multiplexed into one sector, the data in the 1,024 DMA manager units is recorded in one ECC block.

(2) Readout and Complement of DMA Manager

In the data structure described above, the data in the multiple DMA manager units is recorded in each ECC block in the DMA manager. A process of reading out and complementing, if necessary, the information about the DMA manager recorded in units of the ECC blocks will be described.

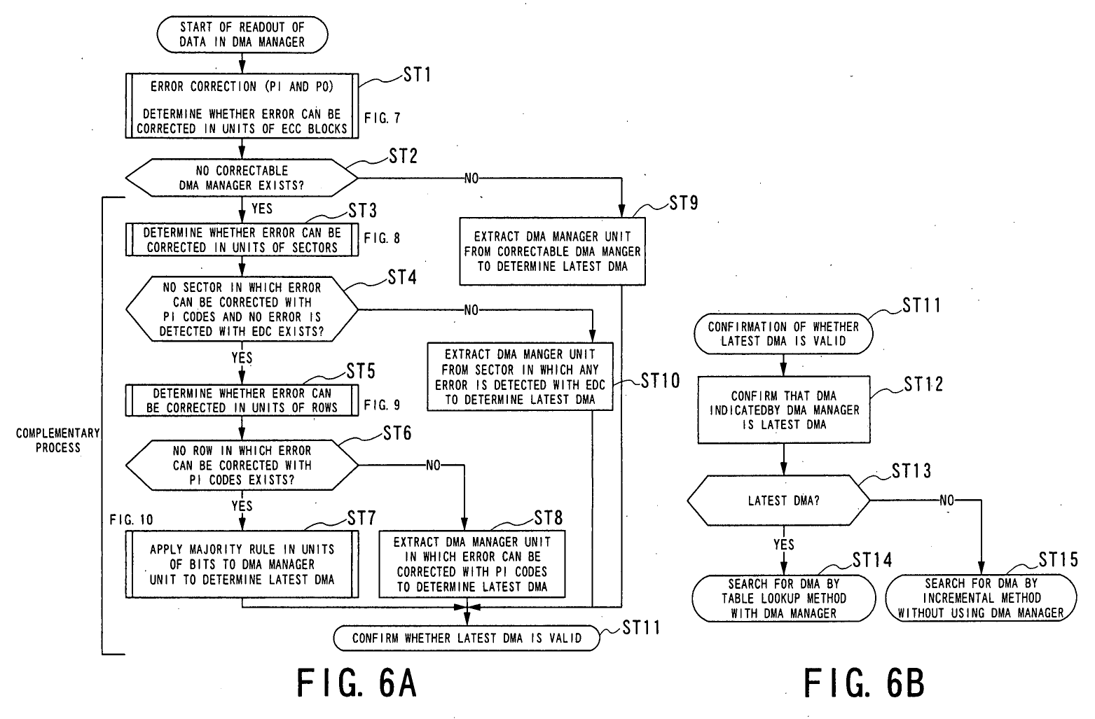

FIG. 6A is a basic flowchart showing the process of reading out and complementing, if necessary, the information about the DMA manager.

In Step ST1, the process reads out the data in the DMA manager in units of the ECC blocks. As described above, the ECC block includes the error correction codes (the PI codes and the PO codes) and the errors can be corrected if the number of the errors is within a predetermined range. Accordingly, in Step ST2, the process determines whether no DMA manager can be corrected in units of the ECC blocks. If the determination is negative, that is, the process determines that a DMA manager that can be corrected in units of the ECC blocks exists (either of the DMA managers 1 and 2 can be corrected), then in Step ST9, the process extracts the DMA manager units from the corrected DMA manager to yield the address information about the latest DMA. If no error occurs, there is no need to correct the DMA manager.

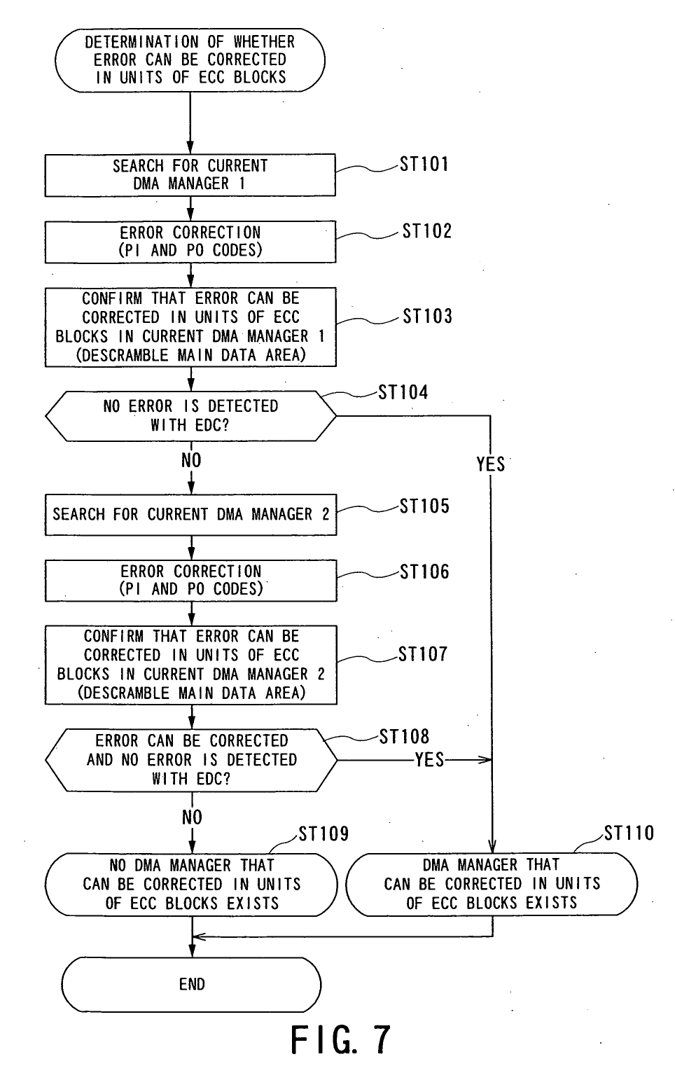

FIG. 7 is a flowchart showing Step ST1 in detail. In Step ST101, the process searches for the current DMA manager 1. As described above, this search is performed by the incremental method. In Step ST102, the process performs the error correction for the current DMA manager 1 with the PI codes and the PO codes in units of the ECC blocks. In Step ST103, the process confirms that the error can be corrected in units of the ECC blocks in the DMA manager 1 and descrambles the main data area in each sector. In Step ST104, the process determines whether any error is detected with the EDC.

If the process determines in Steps ST 103 and ST 104 that an error can be corrected in units of the ECC blocks in the DMA manager 1 and that no error is detected in the error detection with the EDC, it is possible to use the address information in any of the DMA manager units multiplexed into the DMA manager 1 and, therefore, the process determines that “a DMA manager that can be corrected in units of the ECC blocks exists”.

If the process determines in Steps ST103 and ST104 that an error cannot be corrected in units of the ECC blocks in the DMA manager 1 (the number of errors is so large that the error cannot be corrected even with the PI codes and the PO codes) or that any error is detected in the error detection with the EDC, then in Step ST105, the process searches for the latest DMA manager 2. As in the DMA manager 1, in Step ST106, the process performs the error correction with the PI codes and the PO codes in units of the ECC blocks. In Step ST107, the process confirms that the error can be corrected in units of the ECC blocks in the DMA manager 2 and descrambles the main data area in each sector. In Step ST108, the process determines whether any error is detected with the EDC. If the process determines in Steps ST107 and ST108 that the error can be corrected in units of the ECC blocks in the DMA manager 2 and that no error is detected in the error detection with the EDC, the process determines that “a DMA manager that can be corrected in units of the ECC blocks exists”. If the process determines in Steps ST107 and ST108 that the error cannot be corrected in units of the ECC blocks in the DMA manager 2 or that any error is detected in the error detection with the EDC, the error cannot be corrected in units of the ECC blocks in both the DMA managers 1 and 2 and, therefore, the process determines that “no DMA manager that can be corrected in units of the ECC blocks exists”.

If the process determines that “a DMA manager that can be corrected in units of the ECC blocks exists” and has acquired the address information about the latest DMA, a process of confirming whether the acquired address information about the latest DMA is valid (Step ST11 in FIG. 6A) may be performed. This process can improve the reliability of the acquired address information in the DMA.

FIG. 6B is a flowchart showing the process of confirming whether the acquired address information about the latest DMA is valid. In Step ST12, the process confirms that the DMA indicated by the DMA manager is the latest DMA. This confirmation can be performed by several methods. For example, a counter may be provided in the DMA and the counter value may be incremented each time the DMA is replaced with another DMA. Then, the counter value in the DMA, indicated by the DMA manager, may be compared with the counter values in the pervious and subsequent DMAs to determine whether the DMA indicated by the DMA manager is the latest one. Alternatively, the data concerning unused DMAs and used DMAs that are replaced with other DMAs due to defects may be embedded with a certain value that cannot be achieved in the actual operation, for example, with “ffh” (all having a value “1”) to differentiate the unused DMAs and the used DMAs from the latest (current) DMA.

In Step ST13, the process determines whether the DMA indicated by the DMA manager is the latest DMA. If the process determines that the DMA indicated by the DMA manager is the latest DMA, then in Step ST14, the process uses the DMA. If the process determines that the DMA indicated by the DMA manager is not the latest DMA, then in Step ST15, the process abandons the table lookup method with the DMA manager and searches for the latest DMA by the incremental method without using the DMA manager.

Referring back to FIG. 6A, if the process determines in Step ST2 that no DMA manager can be corrected in units of the ECC blocks, the process proceeds to the complementary process subsequent to Step ST2.

In the complementary process subsequent to Step ST2, the process “extracts an active DMA manager unit” from the data that cannot be corrected in units of the ECC blocks or “estimates the data in the DMA manager unit”, based on the fact that the data in the multiple DMA manager units is recorded in the DMA manager, to complement the DMA manager.

The complementary process is roughly grouped into a subprocess (including Steps ST3 and ST4) of performing the error detection in units of sectors to complement the information about the DMA manager, a subprocess (including Steps ST5 and ST6) of performing the error detection in units of rows to complement the information about the DMA manager, and a subprocess (including Step ST 7) of estimating correct data from the multiple DMA manager units based on majority rule.

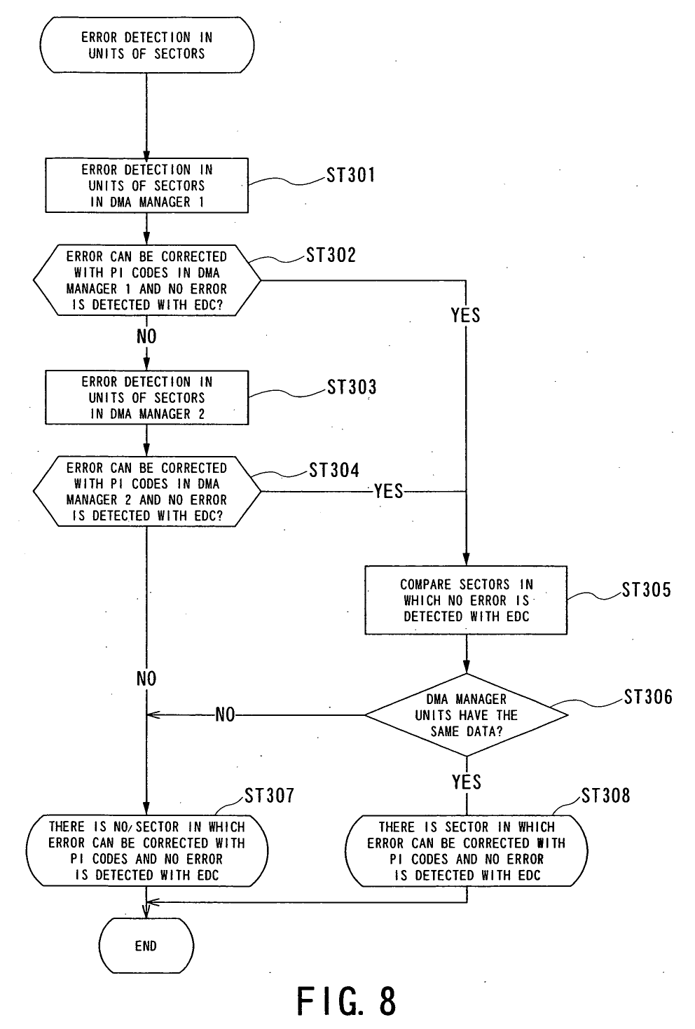

FIG. 8 is a flowchart showing in detail the subprocess of performing the error detection in units of sectors to complement the information about the DMA manager.

In Step ST301, the subprocess performs the error detection for every sector in the DMA manager 1. In Step ST302, the subprocess determines whether the error can be corrected with the PI codes in the DMA manager 1 and whether any error is detected with the EDC. Even if the error cannot be corrected in units of the ECC blocks, the subprocess searches the 32 sectors for any “active sector” to extract the DMA manager units from the “active sector”. As described above with reference to FIGS. 5A and 5B, each sector includes the 12 “rows” and the PI codes are added for every row. If a smaller number of errors occur in the data in a certain row, the “error correction in units of rows” can be performed for the certain row. In addition, since the EDC is added to each sector, the “error detection in units of sectors” can be performed with the EDC.

Hence, the “error correction in units of rows” is performed for all the 12 rows in the sector. If the subprocess determines that an error can be corrected in units of rows, the subprocess determines whether no error is detected in the “error detection in units of sectors” with the EDC after descrambling the main data area. If the subprocess determines that no error is detected in the “error detection in units of sectors” with the EDC, the subprocess determines that the sector is “active”.

The subprocess performs the above steps for all the 32 sectors to extract the “active sector” from the DMA manager 1.

If the determination in Step ST302 is negative, that is, the subprocess determines that no “active sector” exists in the DMA manager 1, then in Steps ST303 and ST304, the subprocess performs the same steps for the DMA manager 2 to extract the “active sector” from the DMA manager 2.

If the determinations in Step ST302 and Step ST304 are affirmative, that is, the “active sector” is extracted from either of the DMA managers 1 and 2, the subprocess determines that there is a sector in which “the error correction with the PI codes can be performed and no error is detected in the error detection with the EDC”. In contrast, if the determinations in Step ST302 and Step ST304 are negative, that is, no “active sector” is extracted from both of the DMA managers 1 and 2, the subprocess determines that there is no sector in which “the error correction with the PI codes can be performed and no error is detected in the error detection with the EDC”.

In the table lookup method, the DMA manager unit can be extracted from the “active sector” and the address information in the DMA, recorded in the DMA manager unit, can be used to immediately access the latest DMA.

The “active sector” includes the multiple DMA manager units. If multiple “active sectors” are extracted, many more DMA manager units exist. In this case, in Step ST305, the subprocess may compare the data in the DMA manager units with each other. If the subprocess determines in Step ST306 that the DMA manager units have the same data, the subprocess may determine that there is a sector in which “the error correction with the PI codes can be performed and no error is detected in the error detection with the EDC”. If the subprocess determines in Step ST306 that the DMA manager units do not have the same data, the subprocess may determine that there is no sector in which “the error correction with the PI codes can be performed and no error is detected in the error detection with the EDC”. This comparison improves the reliability of the acquired address information in the DMA. Alternatively, the subprocess may set an appropriate threshold value for the ratio of the number of the extracted DMA manager units to the number of the DMA manager units having the same data to perform the above determination.

If the subprocess determines that there is a sector in which “the error correction with the PI codes can be performed and no error is detected in the error detection with the EDC” (the determination in Step ST4 in FIG. 6A is negative), then in Step ST10, the subprocess extracts the DMA manager units from the sector in which any error is detected in the error detection with the EDC to determine the latest DMA.

If the subprocess determines that there is no sector in which “the error correction with the PI codes can be performed and no error is detected in the error detection with the EDC” (the determination in Step ST4 in FIG. 6A is affirmative), the process proceeds to the subprocess (Steps ST5 and ST6) of performing the error detection in units of rows to complement the information about the DMA manager.

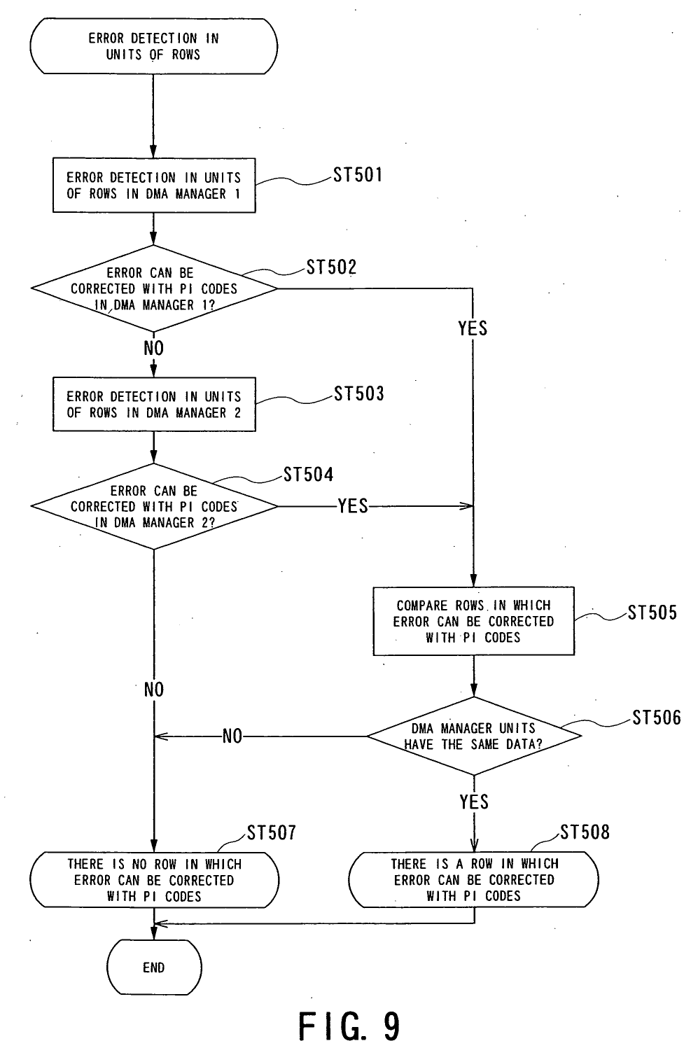

FIG. 9 is a flowchart showing the subprocess (including Steps ST5 and ST6) of performing the error detection in units of rows to complement the information about the DMA manager.

In Step ST501, the subprocess performs the error detection for every row in the DMA manager 1. In Step ST502, the subprocess determines whether the error can be corrected with the PI codes in the DMA manager 1. Even if any error is detected in a sector, the subprocess searches the rows in the sector for any “active row” to extract the DMA manager units from the “active row”. As described above with reference to FIGS. 5A and 5B, each sector includes the 12 “rows” and the PI codes are added for every row. If a smaller number of errors occur in the data in a certain row, the “error correction in units of rows” can be performed for the certain row.

Hence, the “error correction in units of rows” is performed for all the 12 rows in the sector. If the subprocess determines that an error can be corrected in units of rows, the subprocess determines that the row in which the error can be corrected is the “active row”.

The subprocess performs the above steps for all the 192 rows in the ECC block to extract the “active row” from the DMA manager 1.

If the determination in Step ST502 is negative, that is, the subprocess determines that no “active row” exists in the DMA manager 1, then in Steps ST503 and ST504, the subprocess performs the same steps for the DMA manager 2 to extract the “active row” from the DMA manager 2.

In the table lookup method, the DMA manager unit can be extracted from the “active row” after descrambling the main data area and the address information in the DMA, recorded in the DMA manager unit, can be used to immediately access the latest DMA.

If the determinations in Step ST502 and Step ST504 are affirmative, that is, the “active row” is extracted from either of the DMA managers 1 and 2, the subprocess determines that there is a row in which “the error correction with the PI codes can be performed”. In contrast, if the determinations in Step ST502 and Step ST504 are negative, that is, no “active row” is extracted from both of the DMA managers 1 and 2, the subprocess determines that there is no row in which “the error correction with the PI codes can be performed”.

One row has a data size of 172 bytes and the DMA manager unit has a data size of 64 bytes. Accordingly, there are cases in which two DMA manager units exit in the “active row” and in which the DMA manager unit exists across the previous and subsequent rows. In the latter case, if both the rows across which the DMA manager unit exists are “active”, the information about the DMA manager unit across the rows can be extracted as the correct information.

If multiple DMA manager units are extracted, in Step ST505, the subprocess may compare the data in the DMA manager units with each other. If the subprocess determines in Step ST506 that the DMA manager units have the same data, the subprocess may determine that there is a row in which “the error correction with the PI codes can be performed”. If the subprocess determines in Step ST506 that the DMA manager units do not have the same data, the subprocess may determine that there is no row in which “the error correction with the PI codes can be performed”. This comparison improves the reliability of the acquired address information in the DMA. Alternatively, the subprocess may set an appropriate threshold value for the ratio of the number of the extracted DMA manager units to the number of the DMA manager units having the same data to perform the above determination.

If the subprocess determines that there is a row in which “the error correction with the PI codes can be performed” (the determination in Step ST6 in FIG. 6A is negative), then in Step ST8, the subprocess extracts the DMA manager unit in which the error can be corrected with the PI codes to determine the latest DMA.

If the subprocess determines that there is no row in which “the error correction with the PI codes can be performed” (the determination in Step ST6 in FIG. 6A is affirmative), the process proceeds to the subprocess (Step ST7) of estimating correct data from the multiple DMA manager units based on the majority rule.

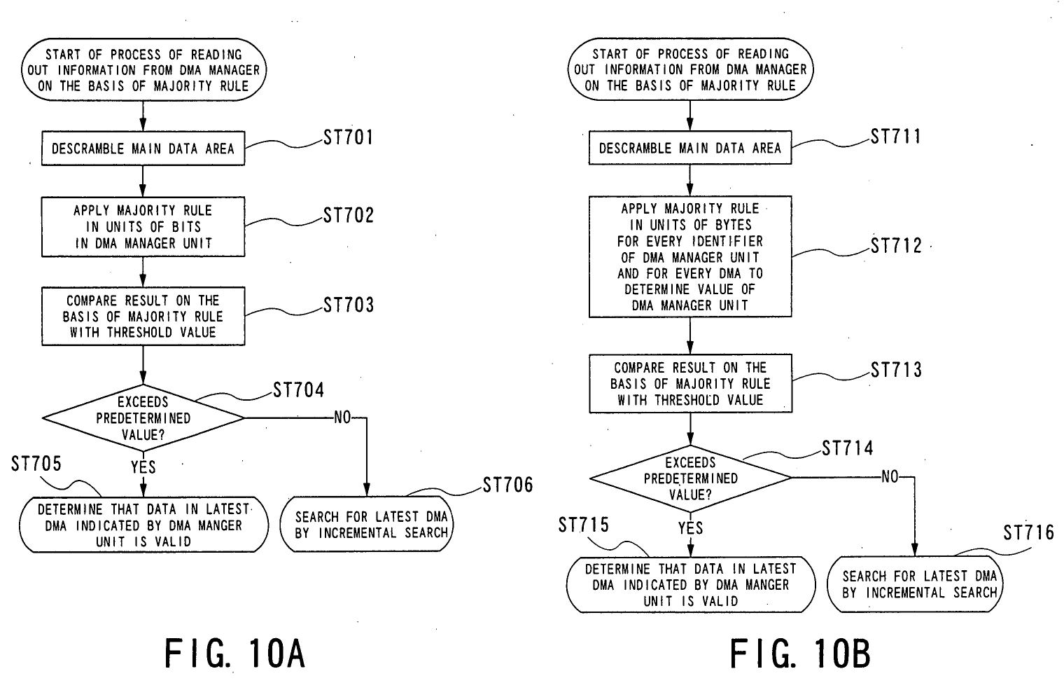

FIGS. 10A and 10B includes flowcharts showing in detail the subprocess of estimating correct data from the multiple DMA manager units based on the majority rule. FIG. 10A is the flowchart in the case of applying the majority rule in units of bits. FIG. 10B is the flowchart in the case of applying the majority rule in units of bytes.

Referring to FIG. 10A, in Step ST701, the process descrambles the main data area for every sector and extracts the DMA manager unit. The extracted DMA manager unit can contain an error. Many DMA manager units exist (a total of 1,024 DMA manager units exist).

Then, in Steps ST702 to ST704, the process estimates a bit value of each bit position by the majority rule. Specifically, the process counts the number of occurrences of bit values (“0” and “1”) at a certain bit position. If the ratio of the number of occurrences of “0” or “1”, which is larger than the number of occurrences of the other value, to the total number of the DMA manager units is higher than or equal to a predetermined threshold value, for example, 90%, the process sets the bit value whose number of occurrences is larger than that of the other value as the bit value at the certain bit position. If the ratio does not exceed the predetermined threshold value, the process regards the bit value at the certain bit position as an indefinite value.

If the bit values are set for all the bit positions and there is no indefinite value, the process estimates the data including the set bit values to be the valid data in the DMA manager unit.

The process refers to the address of the latest DMA in the estimated DMA manager unit to access the DMA.

FIG. 10B is the flowchart in the case of applying the majority rule in units of bytes. In the application of the majority rule in units of bytes, the process compares the byte values (from “0” to “255”) at a certain byte position between the 1,024 DMA manager units. For example, the values of the four bytes in the “first PSN of the current DMA 1” shown in FIG. 4, indicating the position of the DMA 1, are collectively compared between the DMA manager units to count the numbers of occurrences of the byte values and to determine the byte value having the greatest number of occurrences based on the majority rule. In other words, the byte value having the greatest number, among the numbers of occurrences of the byte values, is set as the address of the DMA 1. This approach is adopted in order to classify the DMA manager units on the basis of the “first PSN of the current DMA 1”. If the ratio of the number of occurrences of the byte value that appears most frequently to the total number of the DMA manager units is higher than or equal to a predetermined threshold value, for example, 90%, the process sets the byte value that appears most frequently as the byte value at the certain byte position. If the ratio does not exceed the predetermined threshold value, the process regards the byte value at the certain byte position as an indefinite value.

If the byte values are set for all the byte positions and there is no indefinite value, the process determines the data including the set byte values to be the valid data in the DMA manager unit.

The process refers to the address of the latest DMA in the estimated DMA manager unit to access the DMA.

Although the DMA managers 1 and 2 are determined in this order in all the determinations in units of ECC blocks, in units of sectors, in units of rows, and based on the majority rule in the above description, the determinations may be performed in the reverse order, that is, the DMA managers 2 first, then the DMA manager 1. Alternatively, the DMA manager unit may be first extracted in units of ECC blocks, in units of sectors, and in units of rows in the DMA manager 1, then, the DMA manager unit may then be extracted in units of ECC blocks, in units of sectors, and in units of rows in the DMA manager 2, and the majority rule may be finally adopted.

(3) System Configuration of Information Recording-Reproducing Apparatus

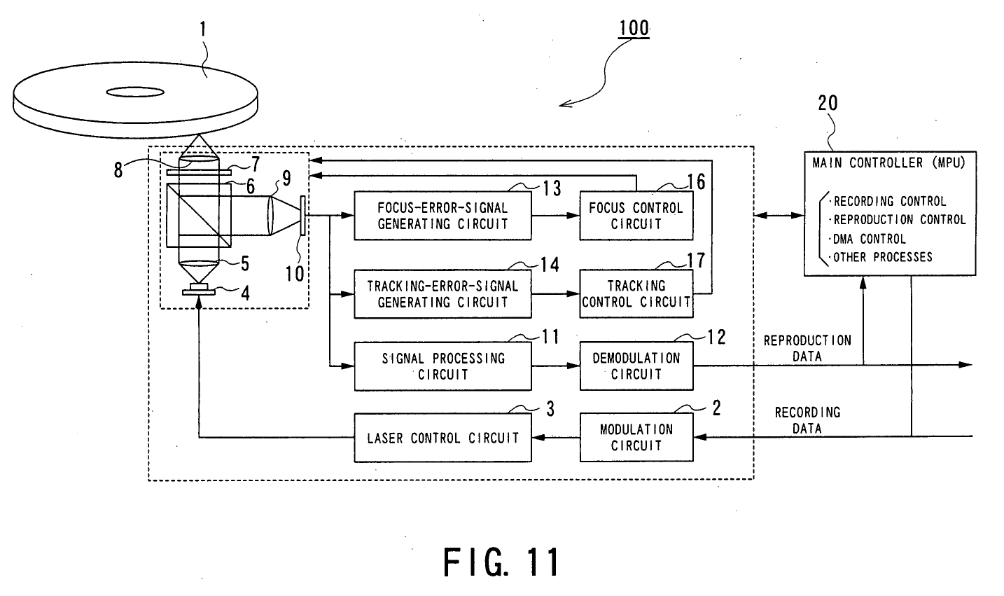

FIG. 11 is a block diagram showing an example of the system configuration of an information recording-reproducing apparatus 100 according to an embodiment of the present invention.

The information recording-reproducing apparatus 100 includes a modulation circuit 2, a laser control circuit 3, a laser 4, a collimator lens 5, a polarization beam splitter (hereinafter abbreviated to “PBS”) 6, a quarter wave plate 7, an objective lens 8, a condenser lens 9, a photosensor 10, a signal processing circuit 11, a demodulation circuit 12, a focus-error-signal generating circuit 13, a tracking-error-signal generating circuit 14, a focus control circuit 16, a tracking control circuit 17, and a main controller 20.

The main controller 20 controls a drive unit. The drive unit includes the modulation circuit 2, the laser control circuit 3, the laser 4, the collimator lens 5, the PBS 6, the quarter wave plate 7, the objective lens 8, the condenser lens 9, the photosensor 10, the signal processing circuit 11, the demodulation circuit 12, the focus-error-signal generating circuit 13, the tracking-error-signal generating circuit 14, the focus control circuit 16, and the tracking control circuit 17.

Data recording in the information recording-reproducing apparatus 100 will now be described. The data recording is controlled by the main controller 20. Recording data (a data symbol) is modulated into a predetermined channel bit sequence by the modulation circuit 2. The channel bit sequence corresponding to the recording data is converted into a pulse waveform driving the laser 4 by the laser control circuit 3. The laser control circuit 3 drives the laser 4 with pulse and records the data corresponding to the predetermined channel bit sequence on the information storage medium 1. A light beam for recording, emitted from the laser 4, is made a parallel light through the collimator lens 5. The parallel light is incident on the PBS 6 and is transmitted through the polarization beam splitter 6. The light beam transmitted through the PBS 6 is transmitted through the quarter wave plate 7 and is condensed on the recording surface of the information storage medium 1 by the objective lens 8. The condensed light beam is subjected to focus control in the focus control circuit 16 and to tracking control in the tracking control circuit 17 so that a desirable minute spot is kept on the recording surface.

Data reproduction in the information recording-reproducing apparatus 100 will now be described. The data reproduction is controlled by the main controller 20. The laser 4 emits a light beam for reproduction in response to a data reproduction instruction supplied from the main controller 20. The light beam for reproduction, emitted from the laser 4, is made a parallel light through the collimator lens 5. The parallel light is incident on the PBS 6 and is transmitted through the polarization beam splitter 6. The light beam transmitted through the PBS 6 is transmitted through the quarter wave plate 7 and is condensed on the recording surface of the information storage medium 1 by the objective lens 8. The condensed light beam is subjected to the focus control in the focus control circuit 16 and to the tracking control in the tracking control circuit 17 so that a desirable minute spot is kept on the recording surface. The light beam for reproduction, with which the information storage medium 1 is irradiated, is reflected from a reflection film or a reflective recording film on the recording surface. The reflected light is transmitted through the objective lens 8 in the opposite direction and is made a parallel light again. The reflected light is transmitted through the quarter wave plate 7 so as to be polarized in the direction perpendicular to the incident light and is reflected from the PBS 6. The light beam reflected from the PBS 6 is made a convergent light through the condenser lens 9 and is incident on the photosensor 10. The photosensor 10 includes, for example, four-divided photodetectors. The luminous flux incident on the photosensor 10 is subjected to photoelectric conversion to be converted into an electrical signal that is amplified. The amplified electrical signal is equalized and binarized by the signal processing circuit 11 and the binarized electrical signal is supplied to the demodulation circuit 12. The signal is subjected to demodulation associated with a predetermined modulation method in the demodulation circuit 12, which outputs reproduction data.

A focus error signal is generated by the focus-error-signal generating circuit 13 on the basis of part of the electrical signal output from the photosensor 10. Similarly, a tracking error signal is generated by the tracking-error-signal generating circuit 14 on the basis of part of the electrical signal output from the photosensor 10. The focus control circuit 16 controls the focusing of the beam spot in response to the focus error signal. The tracking control circuit 17 controls the tracking of the beam spot in response to the tracking error signal.

A replacement process performed in the main controller 20 will now be described. Certification is performed in formatting of the information storage medium 1. The main controller 20 detects any defect on the information storage medium 1. Defect management information about the detected defect, that is, an initial defect is recorded in the PDL in the DMA on the information storage medium 1 by the main controller 20. The defect management information includes the address of the source sector and the address of the destination sector. The main controller 20 detects any defect on the information storage medium 1 also in the normal recording. Defect management information about the detected defect, that is, a secondary defect is recorded in the SDL in the DMA on the information storage medium 1 by the main controller 20. The defect management information includes the address of the first sector of the source ECC block and the address of the first sector of the destination ECC block. An access to the source sector or ECC block is assumed as an access to the destination sector or ECC block on the basis of the PDL and the SDL.

In the information recording-reproducing apparatus 100 according to this embodiment of the present invention, means for recording data on the information storage medium 1 is included in recording control means in the main controller 20. Means for reproducing data on the information storage medium 1 is included in reproduction control means in the main controller 20.

Means for complementing information indicating the position of the DMA, in the DMA manager, is included in DMA control means in the main controller 20.

The information recording-reproducing apparatus 100 according to this embodiment of the present invention is capable of reading out the positional information about the latest DMA stored in a DMA manager to access the DMA in a short time even if the error ratio per ECC block exceeds the error correction capability.

It should be understood by those skilled in the art that various modifications, combinations, sub-combinations and alterations may occur depending on design requirements and other factors insofar as they are within the scope of the appended claims or the equivalents thereof. In addition, appropriate combination of multiple elements in the above embodiments may form embodiments of the present invention. For example, some elements may be deleted from all the elements in the above embodiments or the elements in different embodiments may be appropriately combined.

What is claimed is:

1. An information recording-reproducing apparatus comprising:
a first recording-reproducing unit configured to record user data in a user area on an information storage medium and to reproduce the user data;
a shifting unit configured to shift the user data that cannot be recorded in a defect area in the user area to a spare area on the information storage medium and to reproduce the shifted user data;
a second recording-reproducing unit configured to record defect management information used for reproducing the user data shifted to the spare area in a plurality of defect management areas on the information storage medium and to reproduce the defect management information;
a third recording-reproducing unit configured to record information given by encoding the data in predetermined data blocks with an error correction code, the data blocks being generated by multiplexing information indicating the positions of the defect management areas, on the information storage medium and to decode the encoded information with the error correction code and reproduce the decoded information; and
a complementary unit configured to complement the information indicating the positions of the defect management areas on the basis of the data in data units smaller than the data blocks, when an error can be corrected in the data units or when no error is detected even if the error correction in the data blocks cannot be performed for the information that is encoded and recorded.

2. The information recording-reproducing apparatus according to claim 1,
wherein the complementary unit includes means for comparing the multiplexed information indicating the positions of the defect management areas in units of bits and, if the number of occurrences of the same bit value at a certain bit position exceeds a predetermined threshold value, for setting the bit value to the bit position.

3. The information recording-reproducing apparatus according to claim 1,
wherein the complementary unit includes means for comparing the multiplexed information indicating the positions of the defect management areas in units of bytes and, if the number of occurrences of the same byte value at a certain byte position exceeds a predetermined threshold value, for setting the byte value to the byte position.

4. The information recording-reproducing apparatus according to claim 1,
wherein each data block includes a plurality of sectors in which any error is detected, and
wherein, if no error is detected in at least one of the sectors, the complementary unit extracts the information indicating the positions of the defect management areas from the sector.

5. The information recording-reproducing apparatus according to claim 1,
wherein each data block includes a plurality of rows in which the error can be corrected, and
wherein, if the error correction can be performed for the data in at least one of the rows or if no error is detected in at least one of the rows, the complementary unit extracts the information indicating the positions of the defect management areas from the row.

6. The information recording-reproducing apparatus according to claim 1, further comprising a unit configured to refer to the defect management areas on the basis of the complemented information indicating the positions of the defect management areas and to determine whether the defect management information recorded in the defect management areas that are referred to is the latest defect management information.

7. A method of recording and reproducing information, the method comprising the steps of:
recording user data in a user area on an information storage medium and reproducing the user data;
shifting the user data that cannot be recorded in a defect area in the user area to a spare area on the information storage medium and reproducing the shifted user data;
recording defect management information used for reproducing the user data shifted to the spare area in a plurality of defect management areas on the information storage medium and reproducing the defect management information;
recording information given by encoding the data in predetermined data blocks with an error correction code, the data blocks being generated by multiplexing information indicating the positions of the defect management areas, on the information storage medium and decoding the encoded information with the error correction code to reproduce the decoded information; and
complementing the information indicating the positions of the defect management areas on the basis of the data in data units smaller than the data blocks, when an error can be corrected in the data unit or when no error is detected even if the error correction in the data blocks cannot be performed for the information that is encoded and recorded.

8. The method of recording and reproducing information according to claim 7,
wherein the complementing step includes the step of comparing the multiplexed information indicating the positions of the defect management areas in units of bits and, if the number of occurrences of the same bit value at a certain bit position exceeds a predetermined threshold value, setting the bit value to the bit position.

9. The method of recording and reproducing information according to claim 7,
wherein the complementing step includes the step of comparing the multiplexed information indicating the positions of the defect management areas in units of bytes and, if the number of occurrences of the same byte value at a certain byte position exceeds a predetermined threshold value, setting the byte value to the byte position.

10. The method of recording and reproducing information according to claim 7,
wherein each data block includes a plurality of sectors in which any error is detected, and
wherein, if no error is detected in at least one of the sectors, the information indicating the positions of the defect management areas is extracted from the sector.

11. The method of recording and reproducing information according to claim 7,
wherein each data block includes a plurality of rows in which any error can be corrected, and
wherein, if the error correction can be performed for the data in at least one of the rows or if no error is detected in at least one of the rows, the information indicating the positions of the defect management areas is extracted from the row.

12. The method of recording and reproducing information according to claim 7, further comprising the step of referring to the defect management areas on the basis of the complemented information indicating the positions of the defect management areas and determining whether the defect management information recorded in the defect management areas that are referred to is the latest defect management information.
